(19) United States
(12) Patent Application Publication
(10) Pub. No.: US 2006/0214213 A1
(43) Pub. Date: Sep. 28, 2006

(54) Thin-film capacitor element and semiconductor device

(75) Inventors: John David Bariecki, Kawasaki (JP); Takeshi Shioga, Kawasaki (JP); Kazuaki Kurihara, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/168,935

(22) Filed: Jun. 29, 2005

(30) Foreign Application Priority Data
Mar. 28, 2005 (JP) 2005-91845

(51) Int. Cl. H01L 29/76

(52) U.S. Cl. 257/310

(57) ABSTRACT

A thin-film capacitor element has at least a lower electrode, a ferroelectric layer, and an upper electrode. The upper electrode adds a compressive stress of 10 MPa to 5 GPa to the ferroelectric layer. The upper electrode includes at least one oxide selected from PtOₓ, IrOₓ, RuOₓ, SrRuO_{y}, and LaNiO_{y}.

### CROSS-REFERENCE TO RELATED APPLICATIONS

This application is based upon and claims the benefit of priority from the prior Japanese Patent Application No. 2005-91845, filed on Mar. 28, 2005, the entire contents of which are incorporated herein by reference.

### BACKGROUND OF THE INVENTION

1) Field of the Invention

The present invention relates to a thin-film capacitor element having a capacitor structure formed on a substrate such as a semiconductor substrate by a thin-film manufacturing process, and to a semiconductor device.

2) Description of the Related Art

In recent years, application of a thin-film capacitor element made of a high dielectric constant oxide and ferroelectric oxide is considered as a decoupling capacitor that suppresses voltage noise and a voltage variation in a power bus line, a storage capacitor in a dynamic random access memory (DRAM) and a ferroelectric random access memory (FRAM), and a tunable capacitor in a microwave device. Particularly, in a decoupling capacitor, since the thin-film capacitor element is compact and has a high capacity with excellent microfabricatability, the thin-film capacitor element can be connected to a circuit board by bump connection in a small pitch between terminals. Accordingly, the thin-film capacitor element can decrease mutual inductance, and can work effectively for a low-inductance connection with an LSI. According to these techniques, a high dielectric constant or ferroelectric material selected from perovskite oxide having a pyrochlore structure is used as a dielectric material for a capacitor. The thin-film capacitor element usually has a capacitor structure having a dielectric layer sandwiched between a lower electrode layer and an upper electrode layer on a substrate.

However, the ferroelectric having such structures has an inconvenience in that dielectric characteristics such as a dielectric constant and a dielectric loss decrease as compared with those of the ferroelectric in a bulk state. For example, barium strontium titanate (Ba,Sr) TiO₃ (hereinafter, also referred to as “BST”) has a high dielectric constant exceeding 15,000 near a Curie temperature Tc (308° K. at Ba/Sr=70/30). However, with a BST thin film having platinum (Pt) used as upper and lower electrodes on a silicon (Si) substrate, the dielectric constant decreases to a few hundred. This fact prevents the thin-film capacitor such as BST from being used in actual application.

In general, the internal stress of the perovskite oxide thin film such as BST has a strong influence on change in dielectric constant. For example, when the perovskite oxide thin film has a tensile stress of 100 MPa, the Curie temperature decreases by several dozen of degrees, thereby decreasing the dielectric constant. When the perovskite oxide thin film has a compressive stress of a few hundred MPa, the Curie temperature increases by several dozen of degrees, thereby increasing the dielectric constant. In an actual device such as a thin-film capacitor, the ferroelectric thin film has a laminated structure. Therefore, a stress of a few hundred MPa or more is considered to be applied to the perovskite oxide thin film. The dielectric constant of the perovskite oxide thin film is largely influenced depending on whether the stress is a tensile stress or a compressive stress.

Various mechanisms including a lattice mismatching, a thermal expansion mismatching, and an intrinsic stress at the film forming time are considered as factors of occurrence of an internal stress of the thin film. Techniques of increasing the dielectric constant by positively using these stresses are reported in many devices using the ferroelectric material.

For example, Japanese Patent Application Laid-Open No. 2004-241679 discloses a semiconductor device that includes: a first insulating film formed on a semiconductor substrate; a capacitor lower electrode having a laminated structure of different materials formed on the first insulating film and having a stress of −2×10⁹ to 5×10⁹ dyne/cm²; a dielectric film formed on the capacitor lower electrode; a capacitor upper electrode formed on the dielectric film; and a second insulating film that covers a capacitor including the capacitor lower electrode, the dielectric film, and the capacitor upper electrode. However, in the above patent document, it is explained that a platinum film as a lower electrode film has a compressive stress to prevent the lower electrode film and the ferroelectric layer from being easily peeled off from a base film or the like, and neither the improvement in the dielectric characteristic of the ferroelectric layer nor the influence of the upper electrode is explained.

Japanese Patent Application Laid-Open No. 2000-277701 discloses a semiconductor element including: a lower electrode; a dielectric film formed on an upper surface of the lower electrode; an upper electrode formed on an upper surface of the dielectric film; and a hetero film formed adjacent to the upper electrode so as to induce a compressive stress from the dielectric film. However, according to this technique, although a hetero film is provided on the upper electrode, this hetero film uses a substance compressed in a heat treating. Therefore, the number of manufacturing steps increases, and this makes the manufacturing complex and decreases productivity.

### SUMMARY OF THE INVENTION

The present invention has been achieved in order to solve the above problems. It is an object of the present invention to provide a thin-film capacitor element that uses a substrate made of silicon or the like and ferroelectric to remarkably improve the dielectric constant of the ferroelectric and increase electric capacity, and to provide a semiconductor device.

In order to solve the above problems, a thin-film capacitor element according to the present invention has at least a lower electrode, a ferroelectric or high dielectric constant layer, and an upper electrode, on a substrate. The thin-film capacitor has the upper electrode that adds a compressive stress to the ferroelectric layer. The upper electrode has a residual compressive stress. The compressive stress is added to the ferroelectric layer using this residual compressive stress. The upper electrode has a residual compressive stress of 10 MPa to 5 GPa. One of substances selected from an oxide including PtOₓ (where x represents 2, y represents 3, and the composition may not be a stoichiometric composition, which are also applied to the following substances), IrOₓ, RuOₓ, SrRuO_{y}, and LaNiO_{y}, and a mixture of these substances, is used as a material of the electrodes.

According to the present invention, the semiconductor device includes a source electrode, a drain electrode, a gate electrode, and a thin-film capacitor that are formed on a semiconductor substrate.

### BRIEF DESCRIPTION OF THE DRAWINGS

FIG. 1 is a diagram showing a configuration of a thin-film capacitor element according to the present invention;

FIG. 2 is a cross-sectional diagram of a semiconductor device including the thin-film capacitor element according to the present invention;

FIG. 3 is a diagram showing a thin-film capacitor according to a first embodiment of the present invention;

FIG. 4 is a diagram showing a thin-film capacitor according to a second embodiment of the present invention; and

FIG. 5 is a diagram showing a C—V curve of the thin-film capacitor according to the present invention.

### DETAILED DESCRIPTIONS

Exemplary embodiments of the present invention will be explained below with reference to the accompanying drawings and the like. The description given below is only an example of the embodiments of the present invention, and modifications and variations of the embodiments made within the scope of the invention will readily occur to those skilled in the art, and therefore, do not limit the scope of the present invention.

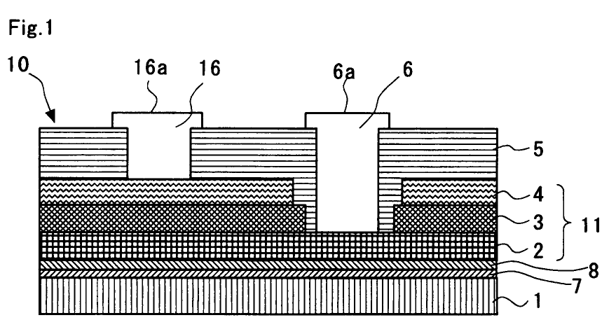

FIG. 1 is a diagram showing a configuration of a thin-film capacitor element according to the present invention. As shown in FIG. 1, a thin-film capacitor element 10 has a silicon (Si) substrate 1. A capacitor structure 11 is formed on the substrate 1 via an insulating film 7 made of SiO₂, and an adhesive layer 8 made of TiO₂. The capacitor structure 11 includes a lower electrode layer 2 such as a Pt electrode, a ferroelectric or high dielectric constant layer 3 such as a (Ba, Sr) TiO₃ layer, and an upper electrode layer 4 such as IrO₂ as an electrode having a compressive stress, in order from the side of the substrate. The upper surface of the capacitor structure 11 is protected by a protective layer 5 formed from an insulation resin such as epoxy resin. Contact holes 6 and 16 are formed on the protective layer 5. A conductive metal such as copper (Cu) is filled in these contact holes. The top surfaces of the contact holes 6 and 16 have electrode pads 6a and 16a, respectively. External terminals such as solder bumps (not shown) can be fitted to the electrode pads 6a and 16a, respectively. An optional electronic element such as a semiconductor element, for example, an LSI chip, can be mounted on the external terminal. Although not shown, the thin-film capacitor element can have one or more additional layers at an optional position, if necessary.

The upper electrode of the thin-film capacitor element 10 according to the present invention has a residual compressive stress. An internal stress can be added to the ferroelectric layer having the internal stress laminated consistently.

According to the thin-film capacitor element 10 that has a perovskite oxide thin film, such as BST and PZT, formed as the ferroelectric layer 3 on the silicon substrate 1, the perovskite oxide thin film has a residual tensile stress, because the film is formed at a high temperature of 400° C. to 700° C. and is then cooled. Therefore, when the film is formed at a higher temperature, an internal tensile stress of a few GPa remains and is applied to the perovskite oxide thin film, thereby decreasing the dielectric constant. In order to decrease the stress due to this thermal expansion mismatching, a substrate such as SrTiO₃ or MgO having a thermal expansion coefficient close to that of the perovskite oxide thin film can be used. However, this substrate is expensive, and severely limits selectivity of a substrate. Further, the stress needs to be adjusted in the manufacturing process.

By changing a film-forming condition for forming the IrO₂ layer on the ferroelectric layer, a residual internal stress can be left in the IrO₂ layer. Based on the internal residual stress in the IrO₂ layer, an internal compressive stress can be added to the ferroelectric layer on the silicon substrate. The residual compressive stress can be identified by measuring a change in the curvature of a laser beam irradiated to the silicon substrate before and after forming the IrO₂ layer.

For example, when an IrO₂ thin film is formed on the silicon substrate by an RF magnetron sputtering method, the internal residual stress can be adjusted by controlling the magnitude of RF power and the thickness of the film formed. When the RF power is changed from 100 W to 80 W, the residual compressive stress of the IrO₂ film can be increased from −3,621 MPa to −5,118 MPa. When the film thickness of the IrO₂ layer is decreased from 100 nm to 50 nm, the compressive stress can be decreased from −3,621 MPa to −2,961 MPa.

According to the thin-film capacitor element 10 of the present invention, the residual compressive stress of the upper electrode 4 is within a range from −10 MPa to −5 GPa. In this case, the “−” sign represents a compressive stress. According to the above measuring method, it is difficult to measure the internal stress of the ferroelectric layer 3 having the upper electrode 4. However, when the upper electrode 4 is formed on the ferroelectric layer 3 by sputtering, vacuum evaporation, or the like and then the formed film is heat treated, there is consistency between the ferroelectric layer 3 and the upper electrode 4. The upper electrode 4 constrains the ferroelectric layer 3, and adds a compressive stress. When the compressive stress is added to the ferroelectric layer 3, a reduction in the dielectric constant of the ferroelectric can be prevented, and dielectric characteristic of polarization or the like per unit area can be improved.

The residual compressive stress of the upper electrode 4 is set within a range from −10 MPa to −5 GPa. When the residual compressive stress is less than −10 MPa, a large compressive stress cannot be added to the ferroelectric layer 3, and therefore, dielectric characteristic cannot be improved. When the residual compressive stress exceeds −5 GPa, the upper electrode 4 is warped, and becomes inconsistent with the ferroelectric layer 3, which may cause peeling off of the upper electrode 4. When a metal upper electrode such as Au is further added to the upper electrode 4 as described later, the peeling off may also occur when the residual compressive stress exceeds −5 GPa. Even when the peeling off does not occur, space is formed by the inconsistency. For example, when a voltage is applied to the thin-film capacitor element 10, a leak current may flow.

As explained above, when IrO₂ or the like having a residual compressive stress is used for the upper electrode 4, it is possible to compensate for a tensile stress that is brought about due to a large difference between the coefficient of thermal expansion of the silicon substrate 1 and that of the ferroelectric 4 such as BST, and that remains after the upper electrode 4 is cooled from a high film-forming temperature of 400° C. to 700° C., thereby preventing a decrease in the dielectric constant of the ferroelectric 4.

According to the thin-film capacitor element 10 of the present invention, the substrate 1 is preferably formed from an electrically insulating material. While the insulating material includes glass, a semiconductor material, and a resin material, the material is not limited to these. A material of the substrate can be selected from the viewpoint of consistency of the thermal expansion coefficient with the ferroelectric layer, and can correspond to various semiconductor devices.

The thin-film capacitor element 10 can further have one or two or more insulating layers 7 laminated on the substrate 1. The insulating layer 7 is preferably formed from at least one kind of insulating material selected from an oxide, a nitride, or an oxynitride of metal, a metal oxide of a high dielectric constant, and an organic resin, or a compound or a mixture of these materials. The insulating layer can be used in the form of a single layer or in the form of a multilayer structure of two or more layers. The insulating material can be selected from the easiness of an epitaxial growth corresponding to the selected semiconductor material or wafer. Based on the above material, the insulating material can correspond to various kinds of semiconductor devices. The capacitor element 10 can have the adhesive layer 8 that increases the coupling strength between the substrate 1 and the capacitor structure 11. The adhesive layer is formed from at least one kind of material selected from a metal made of Pt, Ir, Zr, Ti, TiOₓ (where x represents 2, and the composition may not be a stoichiometric composition, which are also applied to the following substances), IrOₓ, PtOₓ, ZrOₓ, TiN, TiAlN, TaN, TaSiN, an alloy of these metals, a metal oxide, and a metal nitride. The adhesive layer can be used in the form of a single layer, or can be used in a multilayer structure of two or more layers. Particularly, TiOₓ is preferable for the adhesive layer 8. A thin film made of TiOₓ can increase adhesiveness of both the lower electrode made of Pt and the SiO₂ thin film.

Metal of Pt, Pd, Ir, Ru, and the like and a conductive oxide of PtOₓ (where x represents 2, and the composition may not be a stoichiometric composition, which are also applied to the following substances), IrOₓ, RuOₓ, and the like can be used for the material of the lower electrode 2 of the thin-film capacitor element 10. This is because the above material is excellent in oxidation resistance in a high-temperature environment and because a satisfactory crystal orientation control is possible at the time of forming the dielectric layer. According to the present embodiment, Pt is preferably used for the lower electrode. Since Pt has high conductivity and is chemically stable, it is suitable for the lower electrode layer of the ferroelectric thin film. One substance selected from a conductive oxide, their compound, and a mixture of PtOₓ, IrOₓ, and RuOₓ can be used for the material of the lower electrode.

A perovskite oxide having a constitutional formula ABO₃ can be used for the ferroelectric layer 3 of the thin-film capacitor element 10 according to the present invention. In the constitutional formula ABO₃, A represents at least one cation having a positive charge from 1 to 3, and B represents metal of the IVB family (Ti, Zr, or Hf), the VB family (V, Nb, or Ta), the VIB family (Cr, Mo, or W), the VIIB family (Mn or Re), or the IB family (Cu, Ag, or Au), in the periodic table. Specifically, the ferroelectric layer 3 includes (Ba, Sr) TiO₃ (BST), SrTiO₃ (ST), BaTiO₃, Ba (Zr, Ti) O₃, Ba (Ti, Sn) O₃, Pb (Zr, Ti) O₃ (PZT), (Pb, La) (Zr, Ti) O₃ (a layer including any one selected from a perovskite oxide selected from a group structured by PLZT or a mixture including two or more of these dielectric materials, for example), Pb (Mn, Nb) O₃—PbTiO₃ (PMN—PT), Pb (Ni, Nb) O₃—PbTiO₃. This can be selected from the viewpoint of consistency of a lattice grating and a thermal expansion coefficient corresponding to the kind of a substrate that forms the thin-film capacitor element, and the thin-film capacitor element of the present invention can be used for various semiconductor devices.

The upper electrode includes at least on an oxide selected from PtOₓ (where x represents 2, y represents 3, and the composition may not be a stoichiometric composition, which are also applied to the following substances), IrOₓ, RuOₓ, SrRuO_{y}, and LaNiO_{y}. These are conductive oxides which can directly apply an electric field to the ferroelectric layer. Particularly, IrOₓ is most preferable since it has high conductivity, and has high adhesiveness with the lower ferroelectric layer.

Further, in the capacitor structure 11 of the thin-film capacitor element 10 according to the present invention, a metal layer can be laminated on the upper electrode 4 having a compressive stress. The metal layer includes at least one metal selected from metal including Pt, Pd, Ir, Ru, Rh, Re, Os, Au, Ag, and Cu, and their alloy. When the metal layer is provided on the upper electrode including IrO₂, a compressive stress can be further added to the ferroelectric, thereby further improving ferroelectric characteristic.

A semiconductor device can be manufactured by including the thin-film capacitor element according to the present invention. In the process of forming the thin-film capacitor element 10 on the semiconductor substrate 1, the semiconductor layer 1, the insulating layer 7, the adhesive layer 8, the lower electrode layer 3, the ferroelectric layer 3, and the upper electrode layer 4 are sequentially formed, thereby manufacturing the thin-film capacitor element 10.

The insulating layer can be formed by the sputtering method, the thermal oxidation method, the chemical vapor deposition (CVD) method and the like.

The adhesive layer can be formed by the vacuum evaporation method, the sputtering method, the ion plating method, and the like.

The electrode layer can be formed by the vacuum evaporation method, the sputtering method, the plating method such as the physical vapor deposition (PVD) like the ion plating method, the electrolytic plating method, and the electroless plating method, and the like.

The ferroelectric layer can be formed by the sol-gel method, the RF magnetron sputtering, the CVD, and the like.

As circuits that use the capacitor structure 11 according to the present invention, there are circuits of various usages such as a decoupling capacitor in a power supply circuit such as a large-scale integrated circuit, and a tunable capacitor in a microwave device.

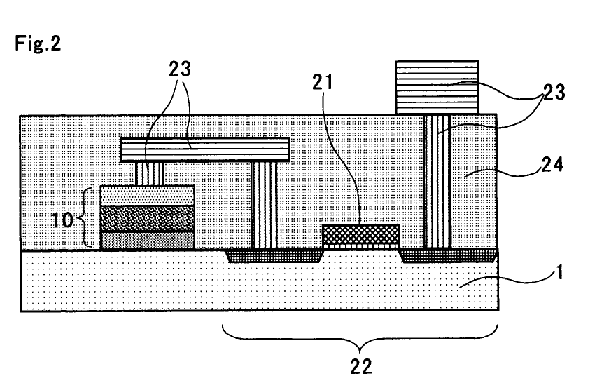

FIG. 2 is a cross-sectional diagram of a semiconductor device including the thin-film capacitor electrode according to the present invention. As shown in FIG. 2, the thin-film capacitor 10 according to the present invention is formed on a part of the surface of the silicon substrate 1, thereby forming a drawing electrode 23. On the other hand, a transistor 22 including a gate, a source, and drain including a gate electrode 21 is formed in another area of the silicon substrate 1. The semiconductor device including the thin-film capacitor element according to the present invention can be manufactured by suitably connecting between the transistor and the capacitor.

In using the thin-film capacitor element 10 according to the present invention, when a circuit is manufactured by employing a parallel structure, a series structure, and a combined structure of the parallel and the series structures, it is possible to obtain a circuit having a capacitor function with a suitable change of capacitance.

As a circuit using the thin-film capacitor element 10 according to the present invention, there is a circuit in various usages such as a storage capacitor in the DRAM and the FRAM circuits.

### Embodiments

The present invention will be explained in further detail below based on several embodiments.

### First Embodiment

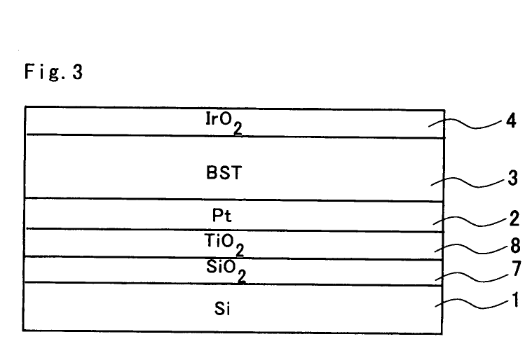

FIG. 3 is a diagram showing a thin-film capacitor according to a first embodiment of the present invention.

First, the adhesive layer 8 made of TiO₂ having a film thickness of 20 nm is formed by the sputtering method via the insulating film 7 made of SiO₂ that is obtained by thermal oxidation on the silicon substrate 1. Next, the lower electrode 2 made of Pt having a film thickness of 100 nm is formed by the sputtering method at a film forming temperature of 250° C. The ferroelectric layer 3 made of a high dielectric material Ba_{0.7}Sr_{0.3}TiO₃ (BST) having a film thickness of 100 nm is formed by the sputtering method at a film forming temperature of 500° C. As a result, a BST/Pt/TiO₂/SiO₂/Si structure is obtained.

When a wafer curvature is measured at this stage, the BST/Pt/TiO₂/SiO₂/Si structure has a tensile stress of +408.2 MPa.

In order to compensate for the tensile stress, an IrO₂ film having a compressive stress within a range from 500 MPa to 5 GPa is formed as the upper electrode 4 on the BST/Pt/TiO₂/SiO₂/Si structure, thereby manufacturing a thin-film capacitor having an IrO₂/BST/Pt/TiO₂/SiO₂/Si structure. When a wafer curvature of this thin-film capacitor is measured, this capacitor has a compressive stress of −740 MPa.

As explained above, it is possible to compensate for a tensile stress generated from the BST/Pt/TiO₂/SiO₂/Si structure. By using IrO₂ in place of Pt for the upper electrode, the dielectric constant of the thin-film capacitor can be significantly increased.

### Second Embodiment

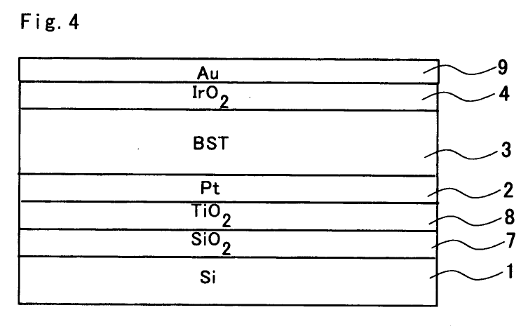

FIG. 4 is a diagram showing a thin-film capacitor according to a second embodiment of the present invention.

In the second embodiment, a metal layer 9 of gold (Au) is formed on the upper electrode 4 of the thin-film capacitor having the IrO₂/BST/Pt/TiO₂/SiO₂/Si structure manufactured in the first embodiment. When a wafer curvature of this thin-film capacitor is measured at this stage, this capacitor has a compressive stress of −787 MPa.

When the metal layer 9 of gold (Au) is formed, the dielectric constant can be further increased from that of the capacitor element having the structure according to the first embodiment.

As explained above, when the compressive stress of at least one of the conductive electrodes of the capacitor element according to the present invention is 10 MPa to 5 GPa, preferably 100 MPa to 5 GPa, the tensile stress of silicon or the like can be compensated for, thereby significantly increasing the dielectric constant.

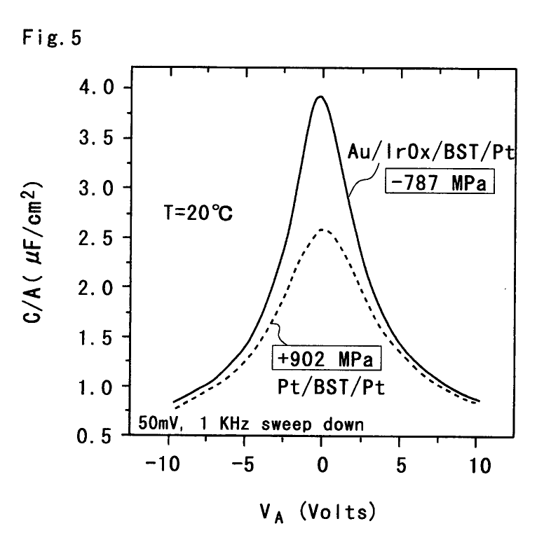

FIG. 5 is a diagram showing a C—V curve of the thin-film capacitor according to the present invention. This diagram shows a C—V curve of the thin-film capacitor having a Pt/BST/Pt/TiO₂/SiO₂/Si structure using the electrode made of Pt having a tensile stress of +902 MPa and the thin-film capacitor having an Au/IrO₂/BST/Pt/TiO₂/SiO₂/Si structure using the electrode made of IrO₂ having a compressive stress of −787 MPa manufactured in the second embodiment.

When IrO₂ is used as a conductive upper electrode having a compressive stress and when an Au film is formed on the upper electrode, the thin-film capacitor element according to the present embodiment has an increase in the electric capacity by 38% from the electric capacity of the thin-film capacitor having the conventional Pt/BST/Pt/TiO₂/SiO₂/Si structure. Further, the thin-film capacitor element according to the present embodiment has a high charge capacity.

According to the present invention, when an electrode and a ferroelectric are laminated on a substrate made of silicon or the like, the internal stress of this electrode is added to the ferroelectric. With this arrangement, it is possible to provide a thin-film capacitor element that can significantly improve the dielectric characteristics such as the dielectric constant and the dielectric loss of the ferroelectric and can increase the electric capacity. Further, it is possible to provide a semiconductor device mounted with this thin-film capacitor element.

What is claimed is:

1. A thin-film capacitor element having at least a lower electrode, a ferroelectric or paraelectric layer, and an upper electrode on a substrate, wherein the upper electrode adds a compressive stress to the ferroelectric layer.

2. The thin-film capacitor element according to claim 1, wherein
the upper electrode includes at least one oxide selected from PtOₓ, IrOₓ, RuOₓ, SrRuO_{y}, and LaNiO_{y}.

3. The thin-film capacitor element according to claim 2, wherein
the upper electrode further includes a metal layer selected from Pt, Au, and Cu.

4. The thin-film capacitor element according to claim 1, wherein
the lower electrode is made of a material selected from Pt, Ir, Ru, PtOₓ, IrOₓ, and RuOₓ.

5. The thin-film capacitor element according to claim 1, wherein
the ferroelectric layer is formed from an oxide having a perovskite structure.

6. The thin-film capacitor element according to claim 5, wherein
the ferroelectric layer is formed from a perovskite oxide selected from (Ba, Sr) TiO₃ (BST), SrTiO₃ (ST), BaTiO₃, Ba (Zr, Ti) O₃, Ba (Ti, Sn) O₃, Pb (Zr, Ti) O₃ (PZT), (Pb, La) (Zr, Ti) O₃ (PLZT).

7. The thin-film capacitor element according to claim 5, wherein
the paraelectric layer is formed from a perovskite oxide selected from (Ba, Sr) TiO₃ (BST), SrTiO₃ (ST), BaTiO₃, Ba (Zr, Ti) O₃, Ba (Ti, Sn) O₃,

8. The thin-film capacitor element according to claim 1, wherein
a residual compressive stress of the upper electrode is within a range from 10 MPa to 5 GPa.

9. The thin-film capacitor element according to claim 1, wherein
the thin-film capacitor has an adhesive layer made of a material selected from Pt, Ir, Zr, Ti, TiOₓ, IrOₓ, PtOₓ, ZrOₓ, TiN, TiAlN, TaN, and TaSiN, between the substrate and the lower electrode.

10. A semiconductor device formed on a semiconductor substrate, and having a source electrode, a drain electrode, and a gate electrode, the semiconductor device having at least a lower electrode, a ferroelectric layer, and an upper electrode on the substrate, wherein the upper electrode adds a compressive stress to the ferroelectric layer.

11. The semiconductor device according to claim 9, wherein
the upper electrode includes at least one oxide selected from PtOₓ, IrOₓ, RuOₓ, SrRuO_{y}, and LaNiO_{y}.

12. The semiconductor device according to claim 9, wherein
the upper electrode further includes a metal layer selected from a group consisting of Pt, Au, and Cu.

13. The semiconductor device according to claim 9, wherein
the ferroelectric layer is formed from an oxide having a perovskite structure.

14. The semiconductor device according to claim 9, wherein
the ferroelectric layer is formed from a perovskite oxide selected from (Ba, Sr) TiO₃ (BST), SrTiO₃ (ST), BaTiO₃, Ba (Zr, Ti) O₃, Ba (Ti, Sn) O₃, Pb (Zr, Ti) O₃ (PZT), (Pb, La) (Zr, Ti) O₃ (PLZT).

15. The semiconductor device according to claim 9, wherein
a residual compressive stress of the upper electrode is within a range from 10 MPa to 5 GPa.
